(19) United States
(12) Patent Application Publication
(10) Pub. No.: US 2019/0011578 A1
(43) Pub. Date: Jan. 10, 2019

(54) X-RAY DETECTOR WITH INTERMEDIATE UNIT AND EVALUATION LEVEL

(71) Applicant: Siemens Healthcare GmbH, Erlangen (DE)

(72) Inventors: Thorsten ERGLER, Erlangen (DE); Harald GEYER, Bubenreuth (DE); Jan WREGE, Erlangen (DE)

(73) Assignee: Siemens Healthcare GmbH, Erlangen (DE)

(21) Appl. No.: 16/026,185

(22) Filed: Jul. 3, 2018

(30) Foreign Application Priority Data
Jul. 10, 2017 (EP) 17180540.1

(51) Int. Cl. G01T 1/24; H01L 27/146

(52) U.S. Cl. CPC G01T 1/242; G01T 1/24; H01L 27/14634; H01L 27/1469; H01L 27/14658

(57) ABSTRACT

An X-ray detector includes at least one converter element, an intermediate unit and a plurality of evaluation units assigned to the at least one converter element. In an embodiment, the plurality of evaluation units are arranged in an evaluation level. Further, the at least one converter element, the intermediate unit and the evaluation level are arranged in a stack arrangement. The at least one converter element and the plurality of evaluation units are connected in an electrically-conducting manner via electrically-conducting connections.

### PRIORITY STATEMENT

The present application hereby claims priority under 35 U.S.C. § 119 to European patent application number EP 17180540.1 filed Jul. 10, 2017, the entire contents of which are hereby incorporated herein by reference.

### FIELD

At least one embodiment of the invention generally relates to an X-ray detector, a medicl device and/or a method for producing the X-ray detector, wherein an intermediate unit and an evaluation level are assigned to at least one converter element.

### BACKGROUND

In the field of X-ray imaging, for example in computed tomography, angiography or radiography, use can be made of counting directly-converting X-ray detectors or integrating indirectly-converting X-ray detectors.

In directly-converting X-ray detectors, the X-rays or photons can be converted into electric pulses by a suitable converter material. The converter material used can, for example, be CdTe, CZT, CdZnTeSe, CdTeSe, CdMnTe, InP, TlBr₂, HgI₂, GaAs or other materials. The electric pulses are evaluated by an evaluation electronics system, for example an integrated circuit (application specific integrated circuit, ASIC).

In counting X-ray detectors, incident X-rays are measured by counting the electric pulses, which are triggered by the absorption of X-ray photons in the converter material. The level of the electric pulse is generally proportional to the energy of the absorbed X-ray photon. This enables the extraction of spectral information by way of a comparison of the level of the electric pulse with a threshold value. The evaluation unit can be provided with so-called through-contacts also called TSVs (English: through silicon vias) so that these forward, the, in particular digital, signals or counted values processed in the evaluation unit on the side facing away from the converter element to a substrate in which rewiring is performed and the, in particular digital, signals can be picked off through a plug via flat ribbon cables.

In indirectly-converting X-ray detectors, the X-rays or photons can be converted into light by a suitable converter material and into electric pulses via photodiodes. Scintillators are frequently used as converter material, for example GOS (Gd₂O_{2S}), CsJ, YGO or LuTAG. Scintillators are in particular used in medical X-ray imaging in the energy range of up to 1 MeV. Typically, so-called indirectly-converting X-ray detectors, so-called scintillator detectors are used in which the X-rays or gamma rays are converted into electric signals in two stages. In a first stage, the X-ray or gamma quanta are absorbed in a scintillator element and converted into optically visible light; this effect is known as luminescence. The light excited by luminescence is then converted in a second stage into an electrical signal by a first photodiode, which is optically coupled to the scintillator element, read out via an evaluation or read-out electronics system and then forwarded to a computing unit.

Known from publication DE 10 2014 213 734 A1 is an imaging apparatus for electromagnetic radiation, in particular for X-ray and/or gamma radiation, including a layering comprising a number of detection elements, a number of read-out boards and a base board, wherein the or each detection element is electrically contacted with a respective read-out board via plurality of first solder contacts, wherein the or each read-out board comprises a plurality of through-contacts and wherein the or each read-out board is electrically contacted with the base board via a plurality of second solder contacts.

Known from publication DE 10 2014 221 829 A1 is a method for producing a sensor board for a detector module, wherein a plurality of read-out units is provided, wherein the read-out units are positioned in a stack structure on a common sensor layer in each case and wherein, after positioning, all read-out units are fixed together on the sensor layer thereby forming a hybrid.

Known from publication DE 10 2014 225 396 B3 is a sensor board for a detector module, which includes, in a stack structure, at least one read-out unit and a sensor layer arranged spaced apart from the read-out unit in the stack direction, wherein, in a longitudinal direction transverse to the stack direction, the sensor comprises, in at least one edge region, a projection with respect to the read-out unit, wherein the interspace formed by the spacing between the sensor layer and the read-out unit is filled with a cured filler material such that at one edge region of the sensor layer is free of the filler material.

### SUMMARY

The inventors have recognized that the converter material can react sensitively to stresses or stress differences as a result of which, particularly in the region of the point of intersection between adjacent evaluation units and along the edges of the adjacent evaluation units, so-called drift behavior can occur which is manifested in the electric pulse or the electric signal of the converter element and hence causes falsification of the signal. The electric signal can, for example, be amplified or attenuated. This drift behavior can in particular result from stresses from a cured filler material.

In embodiments, the application discloses an X-ray detector, a medical device and/or a method for producing the X-ray detector, which enable the reduction of mechanical stresses in the stack structure and homogenization of the electric signals along the planar extension of the converter element.

Embodiments according to the invention are directed to an X-ray detector, a medical device and a method for producing the X-ray detector.

At least one embodiment of the invention relates to an X-ray detector comprising a converter element, an intermediate unit and a plurality of evaluation units assigned to the converter element. The plurality of evaluation units is arranged in an evaluation level. The converter element, the intermediate unit and the evaluation level are arranged in a stack arrangement. The converter element and the evaluation units are connected in an electrically-conducting manner via electrically-conducting connections.

At least one embodiment of the invention further relates to a medical device comprising an X-ray detector according to at least one embodiment of the invention. The advantages of the X-ray detector according to at least one embodiment of the invention can be transferred to the medical device. Particularly advantageously, the homogenization of the electric signals of the converter element can exert an influence on the homogenization of the counted values and hence also on the homogenization of the image created, for example, from the counted values. Advantageously, artefacts in the image induced by the drift inhomogeneities can be reduced. Advantageously, it is possible to reduce or avoid corrections in order to compensate the drift inhomogeneities.

According to one embodiment of the invention, the medical device is a computed tomography system. Advantageously, the measured data, for example counted values, of the X-ray detector can be used to reconstruct layer images, three-dimensional or four-dimensional volume images.

At least one embodiment of the invention further relates to a method for the production of an X-ray detector according to at least one embodiment of the invention including the steps of arrangement and connection-in-an-electrically-conducting-manner. In the arrangement step, the converter element, the intermediate unit and the plurality of evaluation units assigned to the converter element are arranged in a stack arrangement, wherein the plurality of evaluation units is arranged in an evaluation level. In the connection-in-an-electrically-conducting manner step, the converter element and the plurality of evaluation units are connected in an electrically-conducting manner.

### BRIEF DESCRIPTION OF THE DRAWINGS

The following describes example embodiments of the invention with reference to drawings, which show:

FIG. 1 a schematic concept of an X-ray detector according to the invention according to a first embodiment;

FIG. 2 a schematic concept of an X-ray detector according to the invention according to a second embodiment;

FIG. 3 a schematic top view of the intermediate unit and the plurality of evaluation units of the X-ray detector according to the invention according to the first embodiment or the second embodiment;

FIG. 4 a schematic concept of an X-ray detector according to the invention according to a third embodiment;

FIG. 5 a schematic concept of an X-ray detector according to the invention according to a fourth embodiment;

FIG. 6 a schematic top view of the intermediate unit and the plurality of evaluation units of the X-ray detector according to the invention according to the third embodiment or the fourth embodiment;

FIG. 7 a schematic side view of an X-ray detector according to the invention according to a fifth embodiment;

FIG. 8 a schematic side view of an X-ray detector according to the invention according to a sixth embodiment;

FIG. 9 a schematic side view of an X-ray detector according to the invention according to a seventh embodiment;

FIG. 10 a schematic side view of an X-ray detector according to the invention according to an eight embodiment;

FIG. 11 a schematic concept of a computed tomography scanner according to an embodiment of the invention; and

FIG. 12 a schematic concept of a method according to an embodiment of the invention for the production of an X-ray detector according to an embodiment of the invention.

### DETAILED DESCRIPTION OF THE EXAMPLE EMBODIMENTS

The drawings are to be regarded as being schematic representations and elements illustrated in the drawings are not necessarily shown to scale. Rather, the various elements are represented such that their function and general purpose become apparent to a person skilled in the art. Any connection or coupling between functional blocks, devices, components, or other physical or functional units shown in the drawings or described herein may also be implemented by an indirect connection or coupling. A coupling between components may also be established over a wireless connection. Functional blocks may be implemented in hardware, firmware, software, or a combination thereof.

Various example embodiments will now be described more fully with reference to the accompanying drawings in which only some example embodiments are shown. Specific structural and functional details disclosed herein are merely representative for purposes of describing example embodiments. Example embodiments, however, may be embodied in various different forms, and should not be construed as being limited to only the illustrated embodiments. Rather, the illustrated embodiments are provided as examples so that this disclosure will be thorough and complete, and will fully convey the concepts of this disclosure to those skilled in the art. Accordingly, known processes, elements, and techniques, may not be described with respect to some example embodiments. Unless otherwise noted, like reference characters denote like elements throughout the attached drawings and written description, and thus descriptions will not be repeated. The present invention, however, may be embodied in many alternate forms and should not be construed as limited to only the example embodiments set forth herein.

It will be understood that, although the terms first, second, etc. may be used herein to describe various elements, components, regions, layers, and/or sections, these elements, components, regions, layers, and/or sections, should not be limited by these terms. These terms are only used to distinguish one element from another. For example, a first element could be termed a second element, and, similarly, a second element could be termed a first element, without departing from the scope of example embodiments of the present invention. As used herein, the term “and/or,” includes any and all combinations of one or more of the associated listed items. The phrase “at least one of” has the same meaning as “and/or”.

Spatially relative terms, such as “beneath,” “below,” “lower,” “under,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below,” “beneath,” or “under,” other elements or features would then be oriented “above” the other elements or features. Thus, the example terms “below” and “under” may encompass both an orientation of above and below. The device may be otherwise oriented (rotated 90 degrees or at other orientations) and the spatially relative descriptors used herein interpreted accordingly. In addition, when an element is referred to as being “between” two elements, the element may be the only element between the two elements, or one or more other intervening elements may be present.

Spatial and functional relationships between elements (for example, between modules) are described using various terms, including “connected,” “engaged,” “interfaced,” and “coupled.” Unless explicitly described as being “direct,” when a relationship between first and second elements is described in the above disclosure, that relationship encompasses a direct relationship where no other intervening elements are present between the first and second elements, and also an indirect relationship where one or more intervening elements are present (either spatially or functionally) between the first and second elements. In contrast, when an element is referred to as being “directly” connected, engaged, interfaced, or coupled to another element, there are no intervening elements present. Other words used to describe the relationship between elements should be interpreted in a like fashion (e.g., “between,” versus “directly between,” “adjacent,” versus “directly adjacent,” etc.).

The terminology used herein is for the purpose of describing particular embodiments only and is not intended to be limiting of example embodiments of the invention. As used herein, the singular forms “a,” “an,” and “the,” are intended to include the plural forms as well, unless the context clearly indicates otherwise. As used herein, the terms “and/or” and “at least one of” include any and all combinations of one or more of the associated listed items. It will be further understood that the terms “comprises,” “comprising,” “includes,” and/or “including,” when used herein, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list. Also, the term “exemplary” is intended to refer to an example or illustration.

When an element is referred to as being “on,” “connected to,” “coupled to,” or “adjacent to,” another element, the element may be directly on, connected to, coupled to, or adjacent to, the other element, or one or more other intervening elements may be present. In contrast, when an element is referred to as being “directly on,” “directly connected to,” “directly coupled to,” or “immediately adjacent to,” another element there are no intervening elements present.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Before discussing example embodiments in more detail, it is noted that some example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order. Although the flowcharts describe the operations as sequential processes, many of the operations may be performed in parallel, concurrently or simultaneously. In addition, the order of operations may be re-arranged. The processes may be terminated when their operations are completed, but may also have additional steps not included in the figure. The processes may correspond to methods, functions, procedures, subroutines, subprograms, etc.

Specific structural and functional details disclosed herein are merely representative for purposes of describing example embodiments of the present invention. This invention may, however, be embodied in many alternate forms and should not be construed as limited to only the embodiments set forth herein.

Units and/or devices according to one or more example embodiments may be implemented using hardware, software, and/or a combination thereof. For example, hardware devices may be implemented using processing circuity such as, but not limited to, a processor, Central Processing Unit (CPU), a controller, an arithmetic logic unit (ALU), a digital signal processor, a microcomputer, a field programmable gate array (FPGA), a System-on-Chip (SoC), a programmable logic unit, a microprocessor, or any other device capable of responding to and executing instructions in a defined manner. Portions of the example embodiments and corresponding detailed description may be presented in terms of software, or algorithms and symbolic representations of operation on data bits within a computer memory. These descriptions and representations are the ones by which those of ordinary skill in the art effectively convey the substance of their work to others of ordinary skill in the art. An algorithm, as the term is used here, and as it is used generally, is conceived to be a self-consistent sequence of steps leading to a desired result. The steps are those requiring physical manipulations of physical quantities. Usually, though not necessarily, these quantities take the form of optical, electrical, or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, or as is apparent from the discussion, terms such as “processing” or “computing” or “calculating” or “determining” of “displaying” or the like, refer to the action and processes of a computer system, or similar electronic computing device/hardware, that manipulates and transforms data represented as physical, electronic quantities within the computer system's registers and memories into other data similarly represented as physical quantities within the computer system memories or registers or other such information storage, transmission or display devices.

In this application, including the definitions below, the term ‘module’ or the term ‘controller’ may be replaced with the term ‘circuit.’ The term ‘module’ may refer to, be part of, or include processor hardware (shared, dedicated, or group) that executes code and memory hardware (shared, dedicated, or group) that stores code executed by the processor hardware.

The module may include one or more interface circuits. In some examples, the interface circuits may include wired or wireless interfaces that are connected to a local area network (LAN), the Internet, a wide area network (WAN), or combinations thereof. The functionality of any given module of the present disclosure may be distributed among multiple modules that are connected via interface circuits. For example, multiple modules may allow load balancing. In a further example, a server (also known as remote, or cloud) module may accomplish some functionality on behalf of a client module.

Software may include a computer program, program code, instructions, or some combination thereof, for independently or collectively instructing or configuring a hardware device to operate as desired. The computer program and/or program code may include program or computer-readable instructions, software components, software modules, data files, data structures, and/or the like, capable of being implemented by one or more hardware devices, such as one or more of the hardware devices mentioned above. Examples of program code include both machine code produced by a compiler and higher level program code that is executed using an interpreter.

For example, when a hardware device is a computer processing device (e.g., a processor, Central Processing Unit (CPU), a controller, an arithmetic logic unit (ALU), a digital signal processor, a microcomputer, a microprocessor, etc.), the computer processing device may be configured to carry out program code by performing arithmetical, logical, and input/output operations, according to the program code. Once the program code is loaded into a computer processing device, the computer processing device may be programmed to perform the program code, thereby transforming the computer processing device into a special purpose computer processing device. In a more specific example, when the program code is loaded into a processor, the processor becomes programmed to perform the program code and operations corresponding thereto, thereby transforming the processor into a special purpose processor.

Software and/or data may be embodied permanently or temporarily in any type of machine, component, physical or virtual equipment, or computer storage medium or device, capable of providing instructions or data to, or being interpreted by, a hardware device. The software also may be distributed over network coupled computer systems so that the software is stored and executed in a distributed fashion. In particular, for example, software and data may be stored by one or more computer readable recording mediums, including the tangible or non-transitory computer-readable storage media discussed herein.

Even further, any of the disclosed methods may be embodied in the form of a program or software. The program or software may be stored on a non-transitory computer readable medium and is adapted to perform any one of the aforementioned methods when run on a computer device (a device including a processor). Thus, the non-transitory, tangible computer readable medium, is adapted to store information and is adapted to interact with a data processing facility or computer device to execute the program of any of the above mentioned embodiments and/or to perform the method of any of the above mentioned embodiments.

Example embodiments may be described with reference to acts and symbolic representations of operations (e.g., in the form of flow charts, flow diagrams, data flow diagrams, structure diagrams, block diagrams, etc.) that may be implemented in conjunction with units and/or devices discussed in more detail below. Although discussed in a particularly manner, a function or operation specified in a specific block may be performed differently from the flow specified in a flowchart, flow diagram, etc. For example, functions or operations illustrated as being performed serially in two consecutive blocks may actually be performed simultaneously, or in some cases be performed in reverse order.

According to one or more example embodiments, computer processing devices may be described as including various functional units that perform various operations and/or functions to increase the clarity of the description. However, computer processing devices are not intended to be limited to these functional units. For example, in one or more example embodiments, the various operations and/or functions of the functional units may be performed by other ones of the functional units. Further, the computer processing devices may perform the operations and/or functions of the various functional units without sub-dividing the operations and/or functions of the computer processing units into these various functional units.

Units and/or devices according to one or more example embodiments may also include one or more storage devices. The one or more storage devices may be tangible or non-transitory computer-readable storage media, such as random access memory (RAM), read only memory (ROM), a permanent mass storage device (such as a disk drive), solid state (e.g., NAND flash) device, and/or any other like data storage mechanism capable of storing and recording data. The one or more storage devices may be configured to store computer programs, program code, instructions, or some combination thereof, for one or more operating systems and/or for implementing the example embodiments described herein. The computer programs, program code, instructions, or some combination thereof, may also be loaded from a separate computer readable storage medium into the one or more storage devices and/or one or more computer processing devices using a drive mechanism. Such separate computer readable storage medium may include a Universal Serial Bus (USB) flash drive, a memory stick, a Blu-ray/DVD/CD-ROM drive, a memory card, and/or other like computer readable storage media. The computer programs, program code, instructions, or some combination thereof, may be loaded into the one or more storage devices and/or the one or more computer processing devices from a remote data storage device via a network interface, rather than via a local computer readable storage medium. Additionally, the computer programs, program code, instructions, or some combination thereof, may be loaded into the one or more storage devices and/or the one or more processors from a remote computing system that is configured to transfer and/or distribute the computer programs, program code, instructions, or some combination thereof, over a network. The remote computing system may transfer and/or distribute the computer programs, program code, instructions, or some combination thereof, via a wired interface, an air interface, and/or any other like medium.

The one or more hardware devices, the one or more storage devices, and/or the computer programs, program code, instructions, or some combination thereof, may be specially designed and constructed for the purposes of the example embodiments, or they may be known devices that are altered and/or modified for the purposes of example embodiments.

A hardware device, such as a computer processing device, may run an operating system (OS) and one or more software applications that run on the OS. The computer processing device also may access, store, manipulate, process, and create data in response to execution of the software. For simplicity, one or more example embodiments may be exemplified as a computer processing device or processor; however, one skilled in the art will appreciate that a hardware device may include multiple processing elements or processors and multiple types of processing elements or processors. For example, a hardware device may include multiple processors or a processor and a controller. In addition, other processing configurations are possible, such as parallel processors.

The computer programs include processor-executable instructions that are stored on at least one non-transitory computer-readable medium (memory). The computer programs may also include or rely on stored data. The computer programs may encompass a basic input/output system (BIOS) that interacts with hardware of the special purpose computer, device drivers that interact with particular devices of the special purpose computer, one or more operating systems, user applications, background services, background applications, etc. As such, the one or more processors may be configured to execute the processor executable instructions.

The computer programs may include: (i) descriptive text to be parsed, such as HTML (hypertext markup language) or XML (extensible markup language), (ii) assembly code, (iii) object code generated from source code by a compiler, (iv) source code for execution by an interpreter, (v) source code for compilation and execution by a just-in-time compiler, etc. As examples only, source code may be written using syntax from languages including C, C++, C#, Objective-C, Haskell, Go, SQL, R, Lisp, Java®, Fortran, Perl, Pascal, Curl, OCaml, Javascript®, HTML5, Ada, ASP (active server pages), PHP, Scala, Eiffel, Smalltalk, Erlang, Ruby, Flash®, Visual Basic®, Lua, and Python®.

Further, at least one embodiment of the invention relates to the non-transitory computer-readable storage medium including electronically readable control information (processor executable instructions) stored thereon, configured in such that when the storage medium is used in a controller of a device, at least one embodiment of the method may be carried out.

The computer readable medium or storage medium may be a built-in medium installed inside a computer device main body or a removable medium arranged so that it can be separated from the computer device main body. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The term code, as used above, may include software, firmware, and/or microcode, and may refer to programs, routines, functions, classes, data structures, and/or objects. Shared processor hardware encompasses a single microprocessor that executes some or all code from multiple modules. Group processor hardware encompasses a microprocessor that, in combination with additional microprocessors, executes some or all code from one or more modules. References to multiple microprocessors encompass multiple microprocessors on discrete dies, multiple microprocessors on a single die, multiple cores of a single microprocessor, multiple threads of a single microprocessor, or a combination of the above.

Shared memory hardware encompasses a single memory device that stores some or all code from multiple modules. Group memory hardware encompasses a memory device that, in combination with other memory devices, stores some or all code from one or more modules.

The term memory hardware is a subset of the term computer-readable medium. The term computer-readable medium, as used herein, does not encompass transitory electrical or electromagnetic signals propagating through a medium (such as on a carrier wave); the term computer-readable medium is therefore considered tangible and non-transitory. Non-limiting examples of the non-transitory computer-readable medium include, but are not limited to, rewriteable non-volatile memory devices (including, for example flash memory devices, erasable programmable read-only memory devices, or a mask read-only memory devices); volatile memory devices (including, for example static random access memory devices or a dynamic random access memory devices); magnetic storage media (including, for example an analog or digital magnetic tape or a hard disk drive); and optical storage media (including, for example a CD, a DVD, or a Blu-ray Disc). Examples of the media with a built-in rewriteable non-volatile memory, include but are not limited to memory cards; and media with a built-in ROM, including but not limited to ROM cassettes; etc. Furthermore, various information regarding stored images, for example, property information, may be stored in any other form, or it may be provided in other ways.

The apparatuses and methods described in this application may be partially or fully implemented by a special purpose computer created by configuring a general purpose computer to execute one or more particular functions embodied in computer programs. The functional blocks and flowchart elements described above serve as software specifications, which can be translated into the computer programs by the routine work of a skilled technician or programmer.

Although described with reference to specific examples and drawings, modifications, additions and substitutions of example embodiments may be variously made according to the description by those of ordinary skill in the art. For example, the described techniques may be performed in an order different with that of the methods described, and/or components such as the described system, architecture, devices, circuit, and the like, may be connected or combined to be different from the above-described methods, or results may be appropriately achieved by other components or equivalents.

At least one embodiment of the invention relates to an X-ray detector comprising a converter element, an intermediate unit and a plurality of evaluation units assigned to the converter element. The plurality of evaluation units is arranged in an evaluation level. The converter element, the intermediate unit and the evaluation level are arranged in a stack arrangement. The converter element and the evaluation units are connected in an electrically-conducting manner via electrically-conducting connections.

The X-ray detector can preferably be a directly-converting or quantum-counting X-ray detector. The X-ray detector has a stack arrangement. The stack direction can in particular be aligned substantially parallel to the direction of incidence of the X-rays in normal operation. The converter element can in particular have a planar shape. The converter element can in particular have a planar extension. The surface normal of the converter element can preferably extend substantially parallel to the direction of incidence of the X-rays. The intermediate unit can in particular have a planar extension. The surface normal of the intermediate unit can preferably extend substantially parallel to the direction of incidence of the X-rays.

The evaluation unit can in particular have a planar extension. The surface normal of the evaluation unit can preferably extend substantially parallel to the direction of incidence of the X-rays. The majority of the evaluation units is arranged in an evaluation level. The surface normals of the plurality of evaluation units can in particular extend substantially parallel to one another. The plurality of evaluation units can in particular be arranged next to one another such that the plurality of evaluation units has a common level or a common planar extension. The common planar extension of the plurality of evaluation units can be referred to as a planar extension of the evaluation level. The plurality of evaluation units can in particular be assigned to the converter element. An integral number of evaluation units can be assigned to the converter element.

The stack arrangement comprises the following units preferably in the following sequence: the converter element, the intermediate unit and the evaluation level. Herein, the converter element can preferably be arranged closest to the X-ray source so that the X-rays are in particular directly incident on the converter element. The converter element is connected via electrically-conducting connections via the intermediate unit to the evaluation level or the plurality of evaluation units.

Both the converter element and the evaluation units can be subdivided such that a detector element is formed by a sub-region of the converter element and a sub-region of an evaluation unit. Each sub-region can in particular be connected in an electrically-conducting manner to only one sub-region of an evaluation unit. Particularly advantageously, there can be short electrically-conducting connections between the converter element and the evaluation unit in order to keep influences on the signals due to line capacities as low as possible. For this reason, a spatially close arrangement of the converter element and evaluation units is particularly advantageous.

A plurality of evaluation units, preferably embodied as an ASIC, are connected in an electrically-conducting manner to a converter element, also called a sensor. The electrically-conducting connection can also include a mechanical connection or stabilization.

To achieve a better yield and reduce costs during the production of the evaluation units, evaluation units with a smaller planar area than the converter element can be used. The planar extension of the evaluation units can in particular be smaller than the planar extension of the converter element by an integer factor. For example, the planar extension of the evaluation unit can substantially correspond to a quarter of the planar extension of the converter element. For example, 2 to 12 evaluation units can be assigned to the converter element. Preferably 4 evaluation units can be assigned to the converter element.

Interspaces or gaps can be formed between the converter element, the interlayer and the intermediate electrically-conducting connections. Interspaces or gaps can be formed between the plurality of evaluation units, the interlayer and the intermediate electrically-conducting connections. A cavity or a gap can be formed between adjacent evaluation units. Interspaces or gaps can be formed between a possible carrier unit, the plurality of evaluation units and intermediate electrically-conducting connections. The electrically-conducting connections can, for example, be embodied as soldered connections, in particular so-called bump bonds or copper pillars, or as a conducting adhesive connection. In particular between adjacent evaluation units in the evaluation level, gaps between at least two adjacent evaluation units can be formed at the corner points of the evaluation units. In particular, a cross-shaped gap can be formed at points of intersection with four adjacent evaluation units.

The inventors have identified that the arrangement of an intermediate unit between the converter element and the evaluation level enables stresses, in particular in connection with a filler material, in the interspaces, to be reduced. The arrangement of the intermediate unit between the converter element and the evaluation level enables in particular mechanical stresses in the stack structure to be avoided so that the signals along the planar extension of the converter element are uniform.

The intermediate unit can also as be called an interposer. The intermediate unit can comprise glass, silicon, rigid or flexible printed circuit board material. The intermediate unit can substantially have the same planar extension as a converter element or a plurality of converter elements. A unit comprising an evaluation level, intermediate unit and converter element can be called a hybrid structure or hybrid.

Advantageously, the assignment of an intermediate unit to a plurality of evaluation units enables increased mechanical stability to be achieved. It is particularly advantageously possible to reduce the interlayer stresses in the X-ray detector, for example as the result of the shrinkage of a possible filler material in the interspaces. The converter element can, for example, be connected to the interlayer via a soldered or adhesive connection as at least part of the electrically-conducting connection.

Inside the intermediate unit, the electrically-conducting connections lead from the side of the intermediate unit facing the converter to the side of the intermediate unit facing the evaluation level. The evaluation level can, for example, be connected to the interlayer via a soldered or adhesive connection as at least part of the electrically-conducting connection. The electrically-conducting connection can, for example, be divided into three segments: from the converter element to the intermediate unit, through the intermediate unit and from the intermediate unit to the evaluation level. It is advantageously possible to achieve homogeneous drift behavior in the converter element. It is advantageously possible to reduce drift changes or drift inhomogeneities close to the gaps between adjacent evaluation units or the corners and/or edges of evaluation units. It is advantageously possible for the charges or electric pulses along the planar extension to be registered as more homogeneous or more uniform.

According to one embodiment of the invention, more than one converter element is assigned to the intermediate unit. Furthermore, an intermediate unit can be assigned to more than one converter element. Herein, a plurality of evaluation units is assigned to one converter element. For example, the stack structure can comprise two converter elements arranged in a level next to one another, an intermediate unit and in each case four assigned evaluation units per converter element. This stack structure can be part of a sensor board that connects a plurality of converter elements to a detector unit.

The integration or use of an intermediate unit, in particular a so-called interposer, to establish homogeneous stress properties below the converter element or between the converter element and the plurality of evaluation units advantageously enables enhanced mechanical stabilization of the converter element.

According to one embodiment of the invention, the interspaces between the at least one converter element, the intermediate unit and the plurality of evaluation units are filled with a filler material.

In order to obtain sufficient mechanical stabilization of the hybrid or the stack structure of the X-ray detector, it is advantageous to fill the resulting interspaces or gaps between the electrically-conducting connections, for example soldered or adhesive connections, with a filler material or a so-called underfill material. It is advantageously possible for the forces exerted on rotation of the X-ray detector in a computed tomography system to be reduced by the individual electrical connections and distributed over a wide area.

Depending upon the position, for example below the evaluation unit or at the edge of the evaluation unit or at a point of intersection between adjacent evaluation units, mechanical stabilization by way of underfilling and the curing of the filler material can give rise to different stress conditions as a result of shrinkage of the filler material.

Combination of the underfilling with the intermediate unit, advantageously enables a larger selection of filler materials. The gaps or spacings or the size of interspaces between adjacent evaluation units can advantageously be chosen more freely. Advantageously, a curing profile can have greater tolerances for curing or solidification of the filler material.

Advantageously, the stress or the stress difference can be reduced by the combination of intermediate unit and underfilling so that the converter material, for example at a point of intersection, is not associated with a change in the signal and it is possible to reduce or avoid the occurrence of regions with drift changes or drift inhomogeneities.

Advantageously, the interlayer enables a uniform or homogeneous gap or spacing to be achieved between the interlayer and the converter element so that the gaps or the point of intersection between adjacent evaluation units are separated from the converter element by the interlayer. The converter element and the interlayer succeed one another in the stack structure thus enabling the influence of the gaps or the point of intersection between adjacent evaluation units to be reduced or avoided. The evaluation level is separated from the converter element by the interlayer.

In particular, the possible underfilling between the converter element and intermediate unit and the underfilling between intermediate unit and evaluation units can be embodied separately so that possible stresses at the gaps, edges or at the point of intersection between adjacent evaluation units have hardly any influence or no influence on the converter element or the converter element. It is advantageously possible for drift inhomogeneities or an influence of the signals of the converter element to be avoided.

Advantageously, the mechanical stabilization by way of the intermediate unit enables the achievement of more freedom in the selection of the filler material or underfill material and the process control during the curing or solidification of the filler material.

The underfilling comprises a filler material. The filler material can comprise an epoxy compound, a plastic material, a composite or a (pre)polymer. The filler material can comprise a binder material. A matrix can be formed from binder material and filler. The filler material can in particular comprise an epoxy resin. At the time of the filling of the underfilling, for example between the intermediate unit and converter element or evaluation unit, the material of the underfilling, for example comprising epoxy compound, an epoxy resin or a prepolymer, may be liquid or free-flowing. Advantageously, the underfilling can be cured, for example under the influence of temperature.

The underfilling or the filler material can have a thermal conductivity of more than 0.5 W/mK, preferably more than 2 W/mK, particularly preferably more than 6 W/mK. The filler material or the underfilling can preferably be electrically insulated or non-conducting. The filler material can comprise a filler. The filler can have a low, in particular thermal, coefficient of expansion. The filler can, for example, comprise Al₂O₃, SiO₂, BN, AlN, TiN, TiO₂, PZT (PbZrTiO₃), ZrO₂ or YSZ (so-called yttria-stabilized zirconia). The filler can advantageously contribute to the mechanical stability of the stack structure.

The concentration of the filler can be selected such that the viscosity of the filler material, for example in the free-flowing state, is between 3300 mPa·s and 65000 mPa·s. The diameter or size of the filler particles of the filler can in particular be less than the spacing between the intermediate unit and the converter element or the evaluation unit, for example less than 33 percent, preferably 20 percent and particularly preferably 10 percent of the spacing.

The filler can advantageously be adapted to adjust the thermal coefficient of expansion to the adjacent units, for example the converter element, the evaluation unit, the intermediate unit or a possible carrier unit. The shape of the filler particles can, for example, be spherical, round, angular or flocculent. The targeted use of fillers with high thermal conductivities such as, for example, diamond, nanoparticles, graphene or carbon nanotubes can advantageously increase the thermal conductivity of the underfilling. The thermal coefficient of expansion of the underfilling, the filler material or the binder material can, for example, be less than 100 ppm/K and in particular less than 50 ppm/K and preferably be in the region of from 25 to 30 ppm/K.

According to one embodiment of the invention, the stack structure further comprises a carrier unit. The carrier unit can be embodied such that it is assigned at least one stack structure, preferably a plurality of stack structures. The possible carrier unit is connected to the plurality of evaluation units or the evaluation level at least in a mechanical manner, preferably additionally in an electrically-conducting manner. The possible carrier unit can advantageously increase the mechanical stability of the X-ray detector. The possible carrier unit can advantageously be embodied such that the X-ray detector comprises a plurality of stack structures adjacent to one another in a mechanically stable arrangement.

According to one embodiment of the invention, the intermediate unit and the at least one converter element comprise substantially the same planar extension. Advantageously, the intermediate unit can comprise a flat and in particular continuous planar extension spatially opposite to the converter element or parallel to the converter element so that, for example, the spacing between the converter element and the intermediate unit via the planar extension of the converter element is the same. Particularly advantageously, the continuous planar extension of the intermediate unit means that no stresses, or only reduced, stresses are able to form. Advantageously, drift inhomogeneities can be avoided or reduced.

According to one embodiment of the invention, the interlayer has through-contacting of the electrically-conducting connections from the side of the intermediate unit facing the converter element to the side of the intermediate unit of the evaluation level. The interlayer can comprise a, in particular pure or uniform, through-leading or through-contacting of the electrically-conducting connections, i.e. as 1:1-rewiring, from the side of the intermediate unit facing the converter element side of the intermediate unit facing the evaluation unit. Herein, the spatial arrangement or the density of the electrically-conducting connection on the side of the intermediate unit facing the converter element and side of the intermediate unit facing the evaluation unit can be substantially the same.

According to one embodiment of the invention, the interlayer comprises rewiring on the side of the intermediate unit facing the converter element and/or the side of the intermediate unit facing the evaluation level. The interlayer can comprise rewiring on the side of the intermediate unit facing the converter element and/or the side of the intermediate unit facing the evaluation unit with through-leads or through-contacts through the intermediate unit. Herein can the spatial arrangement or the density of the electrically-conducting connection on the side of the intermediate unit facing the converter element and the side of the intermediate unit facing the evaluation unit can differ from one another.

According to one embodiment of the invention, the intermediate unit is embodied in several layers. The intermediate unit can be embodied in several layers, in particular in the case of rewiring on the side of the intermediate unit facing the converter element and/or the side of the intermediate unit facing the evaluation unit.

At least one embodiment of the invention further relates to a medical device comprising an X-ray detector according to at least one embodiment of the invention. The advantages of the X-ray detector according to at least one embodiment of the invention can be transferred to the medical device. Particularly advantageously, the homogenization of the electric signals of the converter element can exert an influence on the homogenization of the counted values and hence also on the homogenization of the image created, for example, from the counted values. Advantageously, artefacts in the image induced by the drift inhomogeneities can be reduced. Advantageously, it is possible to reduce or avoid corrections in order to compensate the drift inhomogeneities.

According to one embodiment of the invention, the medical device is a computed tomography system. Advantageously, the measured data, for example counted values, of the X-ray detector can be used to reconstruct layer images, three-dimensional or four-dimensional volume images.

At least one embodiment of the invention further relates to a method for the production of an X-ray detector according to at least one embodiment of the invention including the steps of arrangement and connection-in-an-electrically-conducting-manner. In the arrangement step, the converter element, the intermediate unit and the plurality of evaluation units assigned to the converter element are arranged in a stack arrangement, wherein the plurality of evaluation units is arranged in an evaluation level. In the connection-in-an-electrically-conducting manner step, the converter element and the plurality of evaluation units are connected in an electrically-conducting manner.

In the arrangement step, the converter element, the intermediate unit and the plurality of evaluation units and optionally the possible carrier unit can be arranged with respect to one another in a stack structure. In the connection-in-an-electrically-conducting-manner step, the converter element, the intermediate unit and the plurality of evaluation units are, for example, connected via soldered connections or an electrically-conducting adhesive connection. The connection-in-an-electrically-conducting-manner step can further comprise the connection-in-an-electrically-conducting-manner of the plurality of evaluation units to the possible carrier unit.

Interspaces can be formed between the converter element and the intermediate unit or the intermediate unit and the evaluation unit or the evaluation unit and a possible carrier unit and filled in the possible filling step. Furthermore, a substrate or a carrier unit can be arranged on the side of the evaluation unit facing away the from converter element and connected to the plurality of evaluation units, for example, via soldered connections or an electrically-conducting adhesive connection. Between the evaluation unit and the substrate, there can be an interspace which can be filled in the possible filling step. Advantageously, increased mechanical stability can be achieved via the intermediate unit.

According to one embodiment of the invention, the arrangement and the connection-in-an-electrically-conducting-manner are performed gradually. The steps of arrangement and connection-in-an-electrically-conducting-manner be performed several times one after the other so that the stack structure is formed level-by-level or layer-by-layer. In the context of embodiments of the invention, ‘gradually’ can mean level-by-level.

According to one embodiment of the invention, the step of connection-in-an-electrically-conducting-manner includes a step-soldering process. The connection-in-an-electrically-conducting-manner can be performed gradually so that the stack structure is formed in several connection steps. Herein, it is possible to use different connection techniques, for example soldering or adhesion. The electrically-conducting connections can have different material compositions and properties, for example a different melting point, along the stack direction. So-called step-soldering can be used for the electrically-conducting connections, wherein the levels of the stack structure are connected in sequence in an electrically-conducting manner via soldered connections with different melting points. Preferably, the lowest melting point can be used between the converter element and the intermediate unit. For example, it is possible to use a so-called reflow soldering process.

According to one embodiment of the invention, the method further includes the step of filling the interspaces. In the filling step, the interspaces between the converter element, the intermediate element and the plurality of evaluation units, and optionally between the plurality of evaluation units and the possible carrier unit, can be filled with a filler material. In the filling step, the filler material can be filled into the interspace or the interspaces in a free-flowing state. The filling can be performed simultaneously for all interspaces in a level or layer of the underfilling or be performed gradually. Advantageously, the underfilling enables stresses to be reduced or avoided.

According to one embodiment of the invention, the filling is performed gradually or level-by-level. The filling can be filled between the different levels of the stack structure, i.e. between the converter element, the intermediate element and the plurality of evaluation units, and optionally between the plurality of evaluation units and the possible carrier unit, simultaneously or gradually, in sequence. The filler material can be different for the interspaces of different levels. For example, a different filler material can be used in the interspaces between the converter element and the intermediate unit, the intermediate element and the plurality of evaluation units and optionally between the plurality of evaluation units and the possible carrier unit. The different filler materials can, for example, differ in viscosity in the free-flowing state and/or in the solidified state, thermal conductivity, thermal coefficient of expansion, transparency to light in the visible, ultraviolet or infrared region or the like.

According to one embodiment of the invention, the method further comprises the step of the solidification of filler material. The solidification can be performed simultaneously or gradually or level-by-level. In the solidification step, the filler material can, for example, be cured via exposure to heat or exposure to UV radiation. The curing creates the underfilling. In the final state, the underfilling comprises a solidified filler material. Advantageously, the X-ray detector has higher mechanical stability.

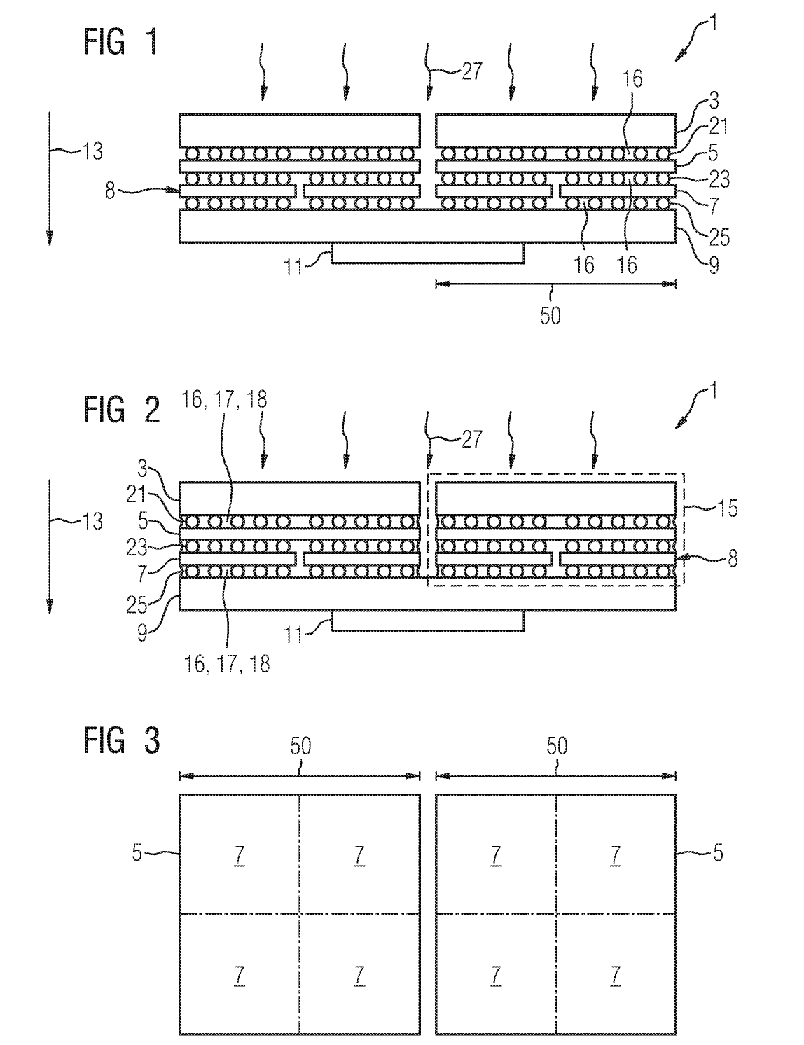

FIG. 1 shows an example embodiment of the Xray detector 1 according to the invention according to a first embodiment. The X-ray detector 1 has a converter element 3, an intermediate unit 5 and a plurality of evaluation units 7 assigned to the converter element 3. The plurality of evaluation units 7 is arranged in an evaluation level 8. The converter element 3, the intermediate unit 5 and the evaluation level 8 are in a stack arrangement. The converter element 3 and the plurality of evaluation units 7 are connected in an electrically-conducting manner via electrically-conducting connections 21, 23, 25. The intermediate unit 5 and the at least one converter element 3 have substantially the same planar extension 50. The stack structure comprises a carrier unit 9. The carrier unit 9 is connected in an electrically-conducting manner to the plurality of evaluation units 7. The carrier unit 9 comprises, on the side or face facing the evaluation level 8, a connecting unit 11, for example a plug. The connecting unit 11 is used to read-out the signals of the X-ray detector 1 and forward them to the computing unit of the medical device.

The X-ray detector 1 is a directly-converting or quantum-counting X-ray detector 1. The X-ray detector 1 comprises a stack arrangement with a stack direction 13. The stack direction 13 is aligned substantially parallel to the conventional direction of incidence of the X-rays 27. The converter element 3 has a planar shape. The converter element 3 has a planar extension. The surface normal of the converter element 3 extends substantially parallel to the direction of incidence of the X-rays 27. The intermediate unit 5 has a planar extension 50. The surface normal of the intermediate unit 5 extends substantially parallel to the direction of incidence of the X-rays 27.

Each evaluation unit 7 has a planar extension, which is smaller than the planar extension 50 of the converter element 3. The surface normal of the plurality of evaluation units 7 extends substantially parallel to the direction of incidence of the X-rays 27. The plurality of evaluation units 7 is arranged in an evaluation level 8. The surface normal of the plurality of evaluation units 7 extend substantially parallel to one another. The evaluation units 7 are arranged next to one another such that the plurality of evaluation units 7 have a common level or a common planar extension 50. The common planar extension 50 of the plurality of evaluation units 7 is termed the planar extension 50 of the evaluation level 8. The plurality of evaluation units 7 is assigned to converter element 3. An integral number of evaluation units 7 is assigned to the converter element 3.

The stack arrangement preferably comprises the following units in the following sequence: the converter element 3, the intermediate unit 5 and the evaluation level 8. The converter element 3 is arranged closest to the X-ray source so that the X-rays 27 are incident on the converter element 3. The converter element 3 is connected to the evaluation level 8 or the plurality of evaluation units 7 via electrically-conducting connections 21, 23 via the intermediate unit 5. Both the converter element 3 and the evaluation units 7 are subdivided such that a detector element is formed by a sub-region of the converter element 3 and a sub-region of an evaluation unit 7. Each sub-region is connected in an electrically-conducting manner to only one sub-region of an evaluation unit 7.

A plurality of evaluation units 7, preferably embodied as ASICs, are connected in an electrically-conducting manner to a converter element 3, also called a sensor. The planar extension of the evaluation units 7 is in particular smaller than the planar extension 50 of the converter element 3 by an integer factor. For example, the planar extension of the evaluation unit 7 can substantially correspond to a quarter of the planar extension 50 of the converter element 3. For example, 2 to 12 evaluation units 7 can be assigned to the converter element 3. For example, 4 evaluation units are assigned to the converter element 3.

Interspaces 16 or gaps are formed between the converter element 3, the interlayer 5 and the intermediate electrically-conducting connections 21. Interspaces 16 or gaps can be formed between the plurality of evaluation units 7, the interlayer 4 and the intermediate electrically-conducting connections 23. A cavity or a gap or an interspace 16 is formed between adjacent evaluation units 7. Interspaces 16 or gaps can be formed between a possible carrier unit 9, the plurality of evaluation units 7 and intermediate electrically-conducting connections 25. The electrically-conducting connections 21, 23, 25 can, for example, be embodied as soldered connections, in particular so-called bump bonds or copper pillars, or as a conductive adhesive connection. Interspaces 16 are formed between at least two adjacent evaluation units 7 in particular between adjacent evaluation units 7 in the evaluation level 8 at the corner points of the evaluation units 7. A cruciform interspace 16 is in particular formed at points of intersection with four adjacent evaluation units 7.

The intermediate unit 5 can also be described as an interposer. The intermediate unit 5 can comprise glass, silicon, rigid or flexible printed circuit board material. The intermediate unit 5 can have substantially the same planar extension 50 as a converter element 3 or a plurality of converter elements 3. A unit comprising an evaluation level 8, intermediate unit 5 and converter element 3 is described as a hybrid structure or hybrid unit 15. The converter element 3 is, for example, connected to the interlayer 5 via a soldered or adhesive connection as at least part of the electrically-conducting connection 21. Inside the intermediate unit 5, the electrically-conducting connections 21, 23 lead from the side of the intermediate unit 5 facing the converter element 3 to the side of the intermediate unit 5 facing the evaluation level 8. The evaluation level 8 can, for example, be connected to the interlayer 5 via a soldered or adhesive connection as at least part of the electrically-conducting connection 23. The electrically-conducting connection 21, 23 can, for example, be divided into three segments: from the converter element 3 to the intermediate unit 5, through the intermediate unit 5 and from the intermediate unit 5 to the evaluation level 8.

FIG. 2 shows an example embodiment of the X-ray detector 1 according to the invention according to a second embodiment. The interspaces 16 between the at least one converter element 3, the intermediate unit 5 and the plurality of evaluation units 7 are filled with a filler material 18. The converter element 3, the intermediate unit 5 and the evaluation level 8 form a hybrid unit 15, for example a 1:4-hybrid unit with a converter element and four evaluation units. The evaluation level 8 is separated from the converter element 3 is by the interlayer 5. In particular, the possible underfilling 17 between the converter element 3 and the intermediate unit 5 and the underfilling 17 between intermediate unit 5 and evaluation units 7 is embodied separately.

The underfilling 17 has a filler material 18. The filler material 18 has an epoxy compound, a plastic material, a composite or a (pre)polymer. The filler material 18 can be a binder material. A matrix can be formed from binder material and filler. The filler material 18 in particular comprises an epoxy resin. At the time of the filling of the underfilling 17, for example between intermediate unit 5 and converter element 3 or evaluation unit 7, the material of the underfilling 17, for example comprising an epoxy compound, can be an epoxy resin or a prepolymer, liquid or free-flowing.

The filler material 18 can comprise a filler. The filler can have a low, in particular thermal, coefficient of expansion. The filler can, for example, comprise Al₂O₃, SiO₂, BN, AlN, TiN, TiO₂, PZT (PbZrTiO₃), ZrO₂ or YSZ (so-called yttria-stabilized zirconia). The filler can advantageously contribute to the mechanical stability of the stack structure. The concentration of the filler can be selected such that the viscosity of the filler material 18, for example in the free-flowing state, is between 3300 mPa·s and 65000 mPa·s. The diameter or size of the filler particles of the filler can in particular be less than the spacing between the intermediate unit 5 and the converter element 3 or the evaluation unit 7, for example less than 33 percent, preferably 20 percent and particularly preferably 10 percent of the spacing. The filler can be adapted to adjust the thermal coefficient of expansion to the adjacent units, for example the converter element 3, the evaluation unit 7, the intermediate unit 5 or a possible carrier unit 9. The filler particles can, for example, have a spherical, round, angular or flocculent shape.

FIG. 3 shows an example embodiment of the X-ray detector 1 according to the invention according to the first embodiment or the second embodiment in a top view of the intermediate unit 5 and the plurality of evaluation units 7. The planar extension 50 of the intermediate unit 5 substantially corresponds to the planar extension 50 of the evaluation level. 2×2 evaluation units 7 are assigned to an intermediate unit 5 in each case. The 2×2 evaluation units 7 form the evaluation level.

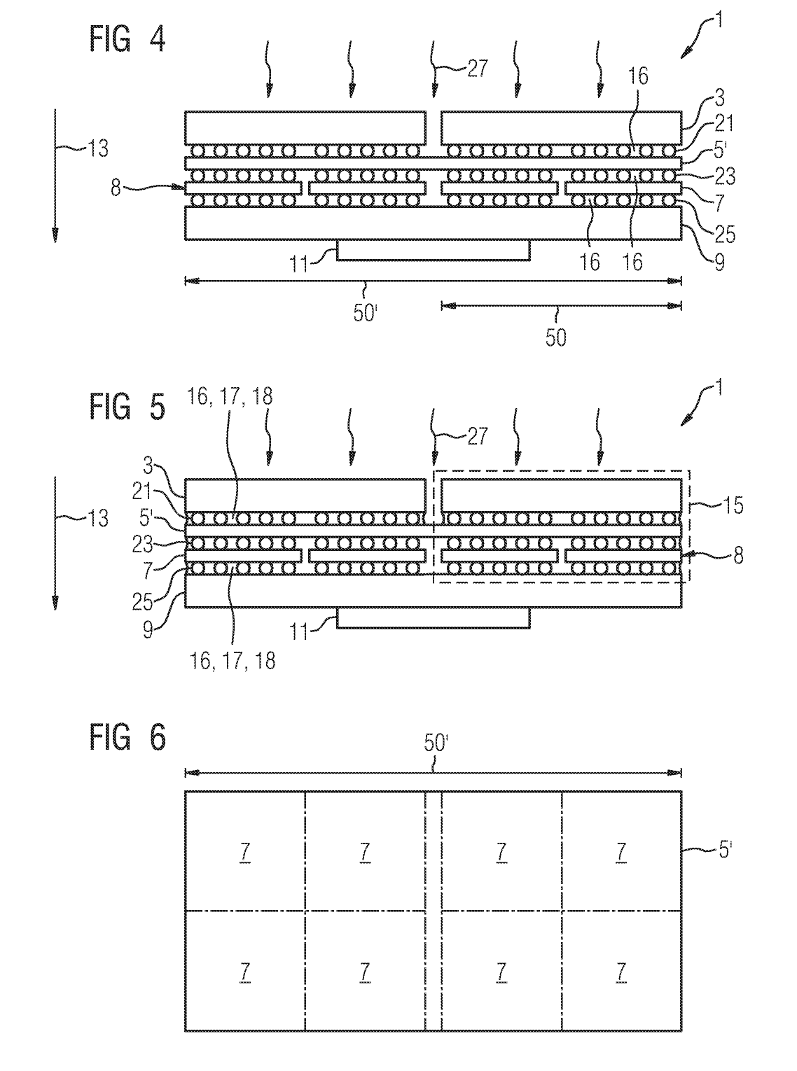

FIG. 4 shows an example embodiment of the X-ray detector 1 according to the invention according to a third embodiment. The X-ray detector 1 has a converter element 3, an intermediate unit 5′ and a plurality of evaluation units 7 assigned to the converter element 3. The converter element 3, the intermediate unit 5′ and the evaluation level 8 are arranged in a stack arrangement. The intermediate unit 5′ and the at least one converter element 3 have substantially same the planar extension 50′. The interlayer 5′ is by way of example assigned to two converter elements 3. Herein, by way of example, four evaluation units 7 are assigned to one converter element 3. For example, the stack structure can include two converter elements 3 arranged in one level next to one another, an intermediate unit 5′ and four assigned evaluation units 7 for each converter element 3 in each case.

FIG. 5 shows an example embodiment of the X-ray detector 1 according to the invention according to a fourth embodiment. The interspaces 16 between the at least one converter element 3, the intermediate unit 5′ and the plurality of evaluation units 7 are filled with a filler material 18.

FIG. 6 shows an example embodiment of the X-ray detector 1 according to the invention according to the third embodiment or the fourth embodiment in a top view of the intermediate unit 5′ and the plurality of evaluation units 7. The planar extension 50′ of the intermediate unit 5′ substantially corresponds to the planar extension 50′ of the evaluation level. 2×4 evaluation units 7 are assigned to the intermediate unit 5′. The 2×4 evaluation units 7 form the evaluation level.

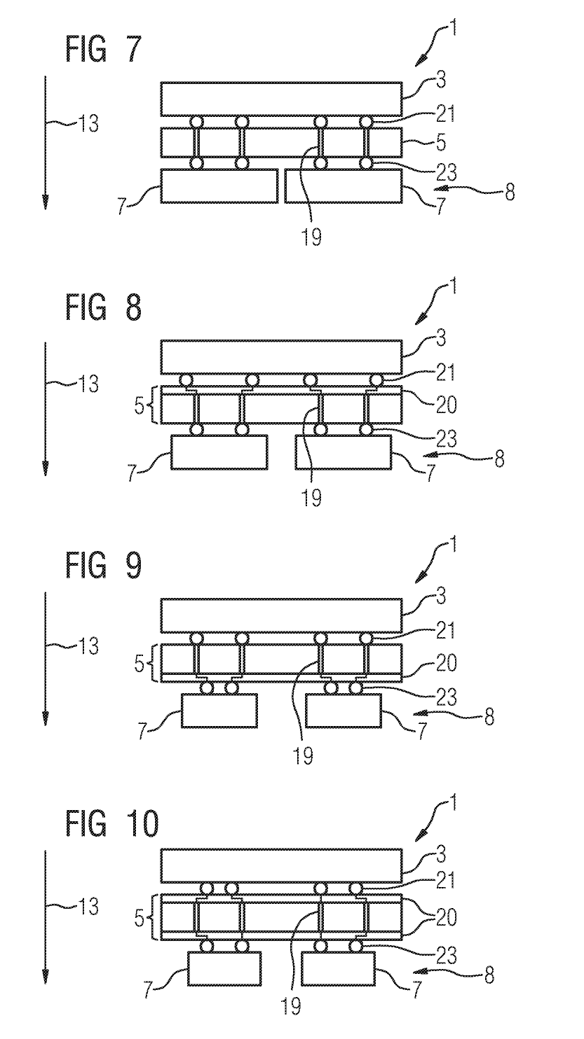

FIG. 7 shows an example embodiment of the X-ray detector 1 according to the invention according to a fifth embodiment in a side view. The interlayer 5 comprises a through-contact 19 of the electrically-conducting connections from the side of the intermediate unit 5 facing the converter element 3 to the side of the intermediate unit 5 facing the evaluation level 8.

FIG. 8 shows an example embodiment of the X-ray detector 1 according to the invention according to a sixth embodiment in a side view. The interlayer 5 comprises a rewiring 20 at the side of the intermediate unit 5 facing the converter element 3. The intermediate unit 5 is embodied in several layers. The evaluation units 7 in each case have a smaller planar extension than in the fifth embodiment. The rewiring 20 enables the planar distribution of the electrically-conducting connections 23 to be changed, for example reduced, compared to the planar distribution of the electrically-conducting connections 21.

FIG. 9 shows an example embodiment of the X-ray detector 1 according to the invention according to a seventh embodiment in a side view. The interlayer 5 comprises a rewiring 20 at the side of the intermediate unit 5 facing the evaluation level 8.

FIG. 10 shows an example embodiment of the X-ray detector 1 according to the invention according to an eighth embodiment in a side view. The interlayer 5 has a rewiring 20 at the side of the intermediate unit 5 facing the converter element 3 and at side of the intermediate unit 5 facing the evaluation level 8.

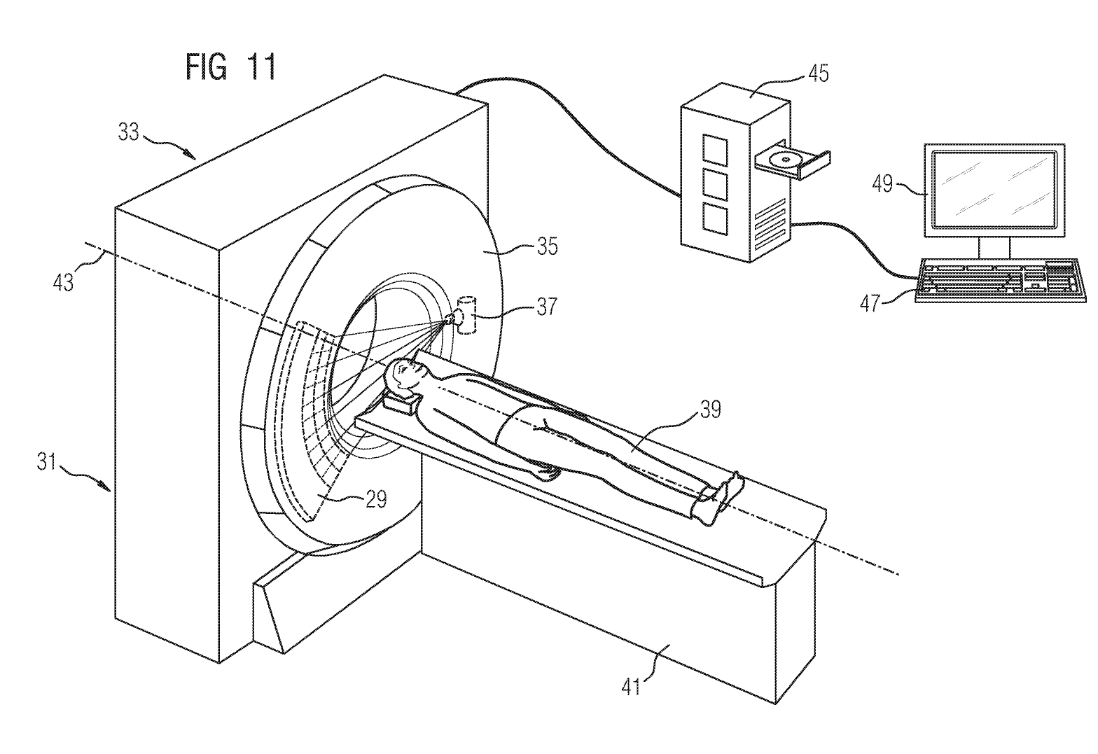

FIG. 11 shows an example embodiment of the computed tomography scanner according to the invention 31 with a detector device 29. The detector device 29 has the X-ray detector according to an embodiment of the invention. The computed tomography scanner 31 contains a gantry 33 with a rotor 35. The rotor 35 comprises an X-ray source 37 and the detector device 29 according to the invention. The patient 39 is mounted on the patent bench 41 and can be moved through the gantry 33 and along the axis of rotation z 43. A computing unit 45 is used to control and calculate the sectional images. An input unit 47 and an output device 49 are connected to the computing unit 45.

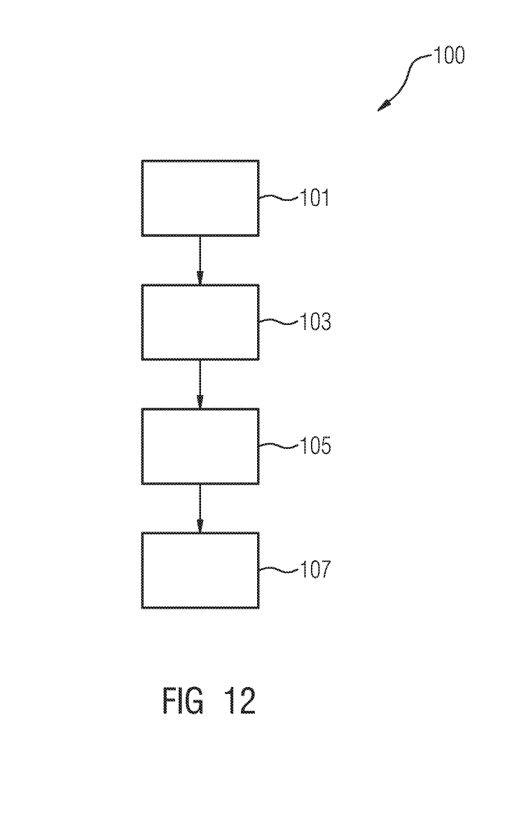

FIG. 12 shows an example embodiment of the method according to the invention 50 for the production of an X-ray detector according to an embodiment of the invention. The method 100 for the production of an X-ray detector according to an embodiment of the invention comprises the steps of arrangement 101 and connection 103. The method 100 can further include the filling step 105. The method 100 can further include the solidification step 107. In the arrangement step 101, the converter element, the intermediate unit and the plurality of evaluation units assigned to the converter element are arranged in a stack arrangement, wherein the plurality of evaluation units is arranged in an evaluation level. In the step of connection-in-an-electrically-conducting-manner 10, the converter element and the plurality of evaluation units are connected in an electrically-conducting manner. In the filling step 105, the interspaces between the converter element, the intermediate element and the plurality of evaluation units are filled with a filler material. In the solidification step 107, the filler material is solidified.

In the arrangement step 101, the converter element, the intermediate unit and the plurality of evaluation units and optionally the possible carrier unit are arranged with respect to one another in a stack structure. In the step of connection-in-an-electrically-conducting-manner 103, the converter element, the intermediate unit and the plurality of evaluation units are, for example, connected via soldered connections or an electrically-conducting adhesive connection. The step of connection-in-an-electrically-conducting-manner 103 can further include the connection-in-an-electrically-conducting-manner of the plurality of evaluation units to the possible carrier unit. Interspaces are formed between the converter element and the intermediate unit or the intermediate unit and the evaluation unit or the evaluation unit and a possible carrier unit and filled in a possible filling step 105. It is furthermore possible for a substrate or a carrier unit to be arranged on the side of the evaluation unit facing away from the converter element and, for example, connected via the connection-in-an-electrically-conducting-manner 103 to the plurality of evaluation units via soldered connections or an electrically-conducting adhesive connection. An interspace can be formed between the evaluation unit and the substrate and filled in the possible filling step 105.

The arrangement 101 and the connection-in-an-electrically-conducting-manner 103 can be performed gradually. The steps of the arrangement 101 and of the connection-in-an-electrically-conducting-manner 103 can herein be performed several times in sequence so that the stack structure is formed level-by-level or layer-by-layer.

The step of connection-in-an-electrically-conducting-manner 103 can in particular include a step-soldering process. The connection-in-an-electrically-conducting-manner 103 can be performed gradually so that the stack structure is formed in a plurality of connection steps. Herein, it is possible to use different connection techniques, for example soldering or adhesion. The electrically-conducting connections can have different material compositions and properties, for example a different melting point, along the stack direction. So-called step-soldering can be used for the electrically-conducting connection, the levels of the stack structure are connected in sequence in an electrically conducting manner via soldered connections with different melting points. Preferably, the lowest melting point can be used between the converter element and the intermediate unit. For example, it is possible to use a so-called reflow soldering process.

In the filling step 105, the interspaces between the converter element, the intermediate element and the plurality of evaluation units, and optionally between the plurality of evaluation units and the possible carrier unit, can be filled with a filler material. In the filling step 105, the filler material can be filled into the interspace or the interspaces in a free-flowing state. The filling 105 can be performed simultaneously for all interspaces in a level or layer of the underfilling or be performed gradually.

The filling 105 can be filled between the different levels of the stack structure, i.e. between the converter element, the intermediate element and the plurality of evaluation units, and optionally between the plurality of evaluation units and the possible carrier unit, simultaneously or gradually, in particular in sequence. The filler material can be different for the interspaces of different levels. For example, a different filter material can be used in the interspaces between the converter element and the intermediate unit, the intermediate element and the plurality of evaluation units, and optionally between the plurality of evaluation units and the possible carrier unit. The different filler materials can, for example differ in the viscosity in the free-flowing state and/or in the solidified state, thermal conductivity, thermal coefficient of expansion, transparency to light in the visible, ultraviolet or infrared region or the like.

The solidification 107 can be performed simultaneously or gradually or level-by-level. In the solidification step 107, the filler material can, for example, be cured via exposure to heat or exposure to UV radiation. The curing creates the underfilling. In the final state, the underfilling has a solidified filler material.

Although the invention was described in more detail by the preferred example embodiment, the invention is not restricted by the disclosed examples and other variations can be derived herefrom by the person skilled in the art without departing from the scope of protection of the invention.

The patent claims of the application are formulation proposals without prejudice for obtaining more extensive patent protection. The applicant reserves the right to claim even further combinations of features previously disclosed only in the description and/or drawings.

References back that are used in dependent claims indicate the further embodiment of the subject matter of the main claim by way of the features of the respective dependent claim; they should not be understood as dispensing with obtaining independent protection of the subject matter for the combinations of features in the referred-back dependent claims. Furthermore, with regard to interpreting the claims, where a feature is concretized in more specific detail in a subordinate claim, it should be assumed that such a restriction is not present in the respective preceding claims.

Since the subject matter of the dependent claims in relation to the prior art on the priority date may form separate and independent inventions, the applicant reserves the right to make them the subject matter of independent claims or divisional declarations. They may furthermore also contain independent inventions which have a configuration that is independent of the subject matters of the preceding dependent claims.

None of the elements recited in the claims are intended to be a means-plus-function element within the meaning of 35 U.S.C. § 112(f) unless an element is expressly recited using the phrase “means for” or, in the case of a method claim, using the phrases “operation for” or “step for.”

Example embodiments being thus described, it will be obvious that the same may be varied in many ways. Such variations are not to be regarded as a departure from the spirit and scope of the present invention, and all such modifications as would be obvious to one skilled in the art are intended to be included within the scope of the following claims.

What is claimed is:

1. An X-ray detector, comprising:
at least one converter element;
an intermediate unit; and
a plurality of evaluation units assigned to the at least one converter element, the plurality of evaluation units being arranged in an evaluation level,
wherein the at least one converter element, the intermediate unit and the evaluation level are arranged in a stack arrangement and
wherein the at least one converter element and the plurality of evaluation units are connected in an electrically-conducting manner via electrically-conducting connections.

2. The X-ray detector of claim 1, wherein interspaces between the at least one converter element, the intermediate unit and the plurality of evaluation units are filled with a filler material.

3. The X-ray detector of claim 1, wherein the stack arrangement further comprises a carrier unit.

4. The X-ray detector of claim 1, wherein the intermediate unit and the at least one converter element have a substantially uniform planar extension.

5. The X-ray detector of claim 1, wherein the intermediate unit has through-contacting of the electrically-conducting connections from a side of the intermediate unit facing the at least one converter element to a side of the intermediate unit facing the evaluation level.

6. The X-ray detector of claim 1, wherein the intermediate unit comprises rewiring on at least one of a side of the intermediate unit facing the at least one converter element and a side of the intermediate unit facing the evaluation level.

7. The X-ray detector of claim 6, wherein the intermediate unit is embodied in several layers.

8. A medical device comprising the X-ray detector of claim 1.

9. The medical device of claim 8, wherein the medical device is a computed tomography system.

10. A method or producing an X-ray detector including at least one converter element, an intermediate unit and a plurality of evaluation units, the method comprising:
arranging the at least one converter element, the intermediate unit and the plurality of evaluation units assigned to the at least one converter element in a stack arrangement, wherein the plurality of evaluation units are arranged in an evaluation level; and
connecting, in an electrically conducting manner, the at least one converter element and the plurality of evaluation units.

11. The method of claim 10, wherein the arranging and the connecting, in an electrically conducting manner, are performed gradually.

12. The method of claim 11, wherein the connecting includes a step-soldering process.

13. The method of claim 10, further comprising:
filling interspaces, between the at least two of the at least one converter element, the intermediate element and the plurality of evaluation units, with a filler material.

14. The method of claim 13, wherein the filling is performed gradually.

15. The method of claim 13, further comprising:
solidifying the filler material.

16. The X-ray detector of claim 2, wherein the stack arrangement further comprises a carrier unit.

17. The X-ray detector of claim 2, wherein the intermediate unit and the at least one converter element have a substantially uniform planar extension.

18. The X-ray detector of claim 2, wherein the intermediate unit has through-contacting of the electrically-conducting connections from a side of the intermediate unit facing the at least one converter element to a side of the intermediate unit facing the evaluation level.

19. A medical device comprising the X-ray detector of claim 2.

20. The medical device of claim 19, wherein the medical device is a computed tomography system.

21. The method of claim 10, wherein the connecting includes a step-soldering process.

22. The method of claim 12, further comprising:
filling interspaces, between the at least two of the at least one converter element, the intermediate element and the plurality of evaluation units, with a filler material.

23. The method of claim 22, wherein the filling is performed gradually.
